(19) United States
(12) Patent Application Publication
(10) Pub. No.: US 2025/0266765 A1
(43) Pub. Date: Aug. 21, 2025

(54) METHOD AND APPARATUS FOR DRIVING TRANSISTOR

(71) Applicant: TEXAS INSTRUMENTS INCORPORATED, Dallas, TX (US)

(72) Inventors: Maik Peter Kaufmann, Freising (DE); Stefan Herzer, Marzling (DE); Michael Lueders, Freising (DE)

(21) Appl. No.: 18/999,954

(22) Filed: Dec. 23, 2024

Related U.S. Application Data
(60) Provisional application No. 63/554,476, filed on Feb. 16, 2024.

(51) Int. Cl. H02M 3/158; H02M 1/32; H03F 3/45; H03K 17/082; H10D 30/47

(52) U.S. Cl. CPC H02M 3/158; H02M 1/32; H03F 3/45273; H03K 17/0822; H10D 30/475; H03K 2217/0063; H03K 2217/0072

(57) ABSTRACT

An apparatus comprising a current source having a current control input and a current source output, the current source output coupled to a first transistor control terminal. The apparatus further comprises a transistor coupled between the first transistor control terminal and a current drain (or sink) terminal, the transistor having a second transistor control terminal. The apparatus further comprises an amplifier having a first input, a second input, and an amplifier output, the first input coupled to the first transistor control terminal, the second input coupled to a reference terminal, and the amplifier output coupled to the current control input and the second transistor control terminal.

### CLAIM OF PRIORITY

This application claims priority to U.S. Provisional Application No. 63/554,476 filed Feb. 16, 2024, titled “Current Source Gate Driver with Voltage Limit,” which is incorporated by reference in its entirety.

### BACKGROUND

Some transistors have control terminals that have DC leakage paths. For example, high electron mobility transistors, such as gallium nitride (GaN) field effect transistors (FETs), can have p-type GaN gate structure with junction having diode characteristic. The diode characteristic is manifested by two diodes. The first diode is a Schottky junction formed between a gate metal to a p-GaN layer in a gate of the GaN FET. The second diode is a PIN diode formed between the p-GaN layer in the gate to a channel between a drain and a source of the GaN FET. One or more of the diodes can provide DC leakage paths through which leakage current can flow. It is desirable to reduce or minimize the leakage current.

### BRIEF DESCRIPTION OF DRAWINGS

The examples will be understood more fully from the detailed description given below and from the accompanying drawings, which, however, should not be taken to limit the disclosure to the specific examples, but are for explanation and understanding only.

FIG. 1 is a schematic illustrating a system where a power converter has a control circuit coupled to a bridge, in accordance with at least one example.

FIG. 2A is a schematic illustrating power converter with control circuits and n-type clamps for high-side and low-side switches, respectively, in accordance with at least one example

FIG. 2B is a plot illustrating an exponential function of VGS versus current for a GaN transistor used for high-side and low-side switches.

FIG. 2C is a schematic illustrating the power converter with current limiter circuits and p-type clamps for high-side and low-side switches, respectively, in accordance with at least one example.

FIG. 3 is a schematic illustrating a first portion of the power converter with p-type clamp for the low-side switch, in accordance with at least one example.

FIG. 4 is a schematic illustrating a second portion of the power converter with p-type clamp for the high-side switch, in accordance with at least one example.

FIG. 5 is a schematic illustrating the portion of the control circuit with p-type clamp and associated current reference circuit for the low-side switch, in accordance with at least one example.

FIG. 6 is a schematic illustrating a portion of the control circuit with p-type clamp and associated current reference circuit for the high-side switch, in accordance with at least one example.

FIGS. 7A and 7B are schematics illustrating reference voltage generation circuits for the control circuits, in accordance with some examples.

FIG. 8A is a flowchart of a method of driving a transistor, and FIG. 8B is the associated timing diagram, in accordance with at least some examples.

### SUMMARY

In at least one example, an apparatus comprises a current source having a current control input and a current source output, the current source output coupled to a first transistor control terminal. The apparatus further comprises a transistor coupled between the first transistor control terminal and a current drain (or sink) terminal, the transistor having a second transistor control terminal. In at least one example, the apparatus further comprises an amplifier having a first input, a second input, and an amplifier output, the first input coupled to the first transistor control terminal, the second input coupled to a reference terminal, and the amplifier output coupled to the current control input and the second transistor control terminal.

In at least one example, an apparatus comprises a current source having a current source control input and a current source output, the current source output coupled to a transistor control terminal. The apparatus further comprises a current sink having a current sink control input and coupled between the transistor control terminal and a current drain terminal. In at least one example, the apparatus further comprises an amplifier having a first input, a second input, and an amplifier output, the first input coupled to the current source output, the second input coupled to a reference terminal, and the amplifier output coupled to the current source control input and the current sink control input.

In at least one example, an apparatus comprises a current source and a current sink coupled to a transistor control terminal, and an amplifier configured to control the current source and the current sink by sensing a voltage at the transistor control terminal.

In at least one example, a method comprises injecting a first current to a control terminal of a transistor. Responsive to a voltage of the control terminal exceeding a threshold, reducing the first current, and the method comprises sinking a second current from the control terminal. In at least one example, responsive to the voltage being at the threshold, the method further comprises maintaining the first current at a non-zero value.

### DETAILED DESCRIPTION

As described above, some transistors have control terminals that have DC leakage paths. For example, high electron mobility transistors, such as gallium nitride (GaN) field effect transistors (FETs), can have p-type GaN gate structure with junction having diode characteristic. The diode characteristic is manifested by two diodes. The first diode is a Schottky junction formed between a gate metal to a p-GaN layer in a gate of the GaN FET. The second diode is a PIN diode formed between the p-GaN layer in the gate to a channel between a drain and a source of the GaN FET. One or more of the diodes can provide DC leakage paths through which leakage current can flow. The amount of leakage current (e.g., in the form of a gate current) flowing through the diodes can increase with the gate-source voltage of the transistor. For example, at a desired on-state gate-source voltage (e.g., 6V), the gate current for a 200 mOhm p-GaN gate FET can be as high as 1.5 mA. This current follows a diode characteristic and can increase exponentially with the gate-source voltage. For example, the gate current can experience an approximately 10% increase for a gate-to-source voltage (VGS) increase of 0.5V. The gate current can also have a strong temperature dependence (e.g., higher current at higher temperature). The exponential increase of the gate current increases the overall power consumption.

Another challenge is maintaining the reliability and integrity of the GaN FET. Specifically, a large gate current can damage the gate structure and degrade the reliability and integrity of the GaN FET. Also, the integrity and reliability of gate structure of the GaN FET may have high sensitivity to over voltages, which may show at least a multi-fold decrease (e.g., 10x decrease) of time dependent dielectric breakdown (TDDB) lifetime for 0.5V increase of gate-source voltage. In a first quadrant conduction (e.g., positive current flow from drain to source), the gate-source voltage can be controlled since a gate driver is referred to the source of the GaN FET, which is the lowest potential applied to the GaN FET. Thus, a maximum 6V gate-to-channel can be maintained, since the drain potential is equal to or higher than the source potential. In a third quadrant conduction (positive current flow from source to drain), however, this is more challenging since the maximum gate-to-channel voltage is at the drain edge of the gate. For example, for a 200 mOhm nominal GaN FET, the on-resistance at 150 C can be as high as 600 mOhm. At a typical current of 1.5A, this leads to nearly 1V drop across the GaN FET. Thus, in the third quadrant conduction, the drain is typically 1 V lower than the source. When a gate driver controls VGS at 6V, this leads to approximately 7V gate-to-drain voltage (VGD) with the corresponding lifetime reduction of up to 100x. In this condition, the gate-current also increases by approximately 10-100x due to the higher forward voltage across the gate junction which leads to increased quiescent current in the third quadrant.

The present disclosure provides examples that can address at least some of these issues. In at least one example, a gate driver is provided to maintain the on-state gate-source of a HEMT with p-type GaN gate (e.g., at 6V or other voltages) while providing a predetermined current to the gate/control terminal. In at least one example, the gate driver includes a current source and a current sink each coupled to a transistor control terminal/gate. An amplifier is configured to control, through a feedback loop that senses a voltage at the transistor control terminal, the amount of gate current supplied to the transistor control terminal, by controlling the current source and the current sink. The amplifier can control the amount of gate current supplied to the transistor control terminal so that the on-state gate-source voltage, during steady state, does not exceed a voltage threshold. In at least one example, a pull-up path of the current source gate driver is implemented as the current source, which can limit the amount of gate current supplied to pull up the gate-source voltage to a current threshold (e.g., a maximum allowed quiescent current). For example, the gate current is restricted to a predetermined value (e.g., 0.5 mA) so that the gate current does not exceed a maximum quiescent current. Also, by sensing and controlling the gate-source voltage to be below or equal to a voltage threshold, the gate can be protected from overvoltage. In at least one example, the current sink can also be controlled to limit the gate-source voltage. For example, in examples with low GaN FET gate leakage (e.g., due to process variation, low temperature, etc.). If the gate-source voltage of the GaN FET is at or exceeds a desired value (e.g., 6V), the current sink can be activated to sink/reduce the gate current supplied to the transistor control terminal, to limit the on-state gate-source voltage. In at least one example, the current sink comprises a transistor that can be controlled by the amplifier to operate as a clamp device to, for example, sink/drain away some of the gate current responsive to the gate-source voltage exceeding a voltage threshold, to bring down the gate-source voltage.

In some examples, the gate driver with a current source and a current sink to limit gate-source voltage and gate current, as described above, can be an auxiliary gate driver that operate together with a main gate driver in driving the gate/control terminal of transistor. For example, the main gate driver can provide the on-state gate current until a first current threshold is reached, and if the on-state gate current exceeds the first current threshold (e.g., due to process variation, temperature, etc.), the auxiliary gate driver can provide additional current to the transistor control terminal, while maintaining the on-state gate current at (or below) a second current threshold and maintaining on-state gate-source voltage at (or below) a voltage threshold.

In at least one example, a gate driver with a current source and a current sink to limit gate-source voltage and gate current, as described above, is implemented for each of a high-side switch and a low-side switch of a half bridge circuit. The half bridge circuit can be part of a power converter used for any high-voltage application (e.g., fan, electric vehicle, electric motor, etc.).

Examples of a gate driver as described herein can provide various advantages. For example, the power consumption of the gate driver in maintaining the on-state gate current can be reduced by restricting/limiting the on-state gate-source voltage, thereby reducing/avoiding the aforementioned exponential increase of the gate current through the diode leakage paths with gate-source voltage increase. Through a feedback loop that monitors the voltage at the gate of the GaN FET and adjusts the current of the current source when the voltage on the gate crosses a threshold, the precision in controlling the gate current across, for example, different processes, voltage supplies, and temperatures can also be improved. Further, the current of the current source can be trimmed which allows for finer control of the current to the gate of the GaN FET when the GaN FET is turned on. All these can improve the performance of the gate driver.

Here, the same reference numbers or other reference designators are used in the drawings to designate the same or similar (either by function and/or structure) features.

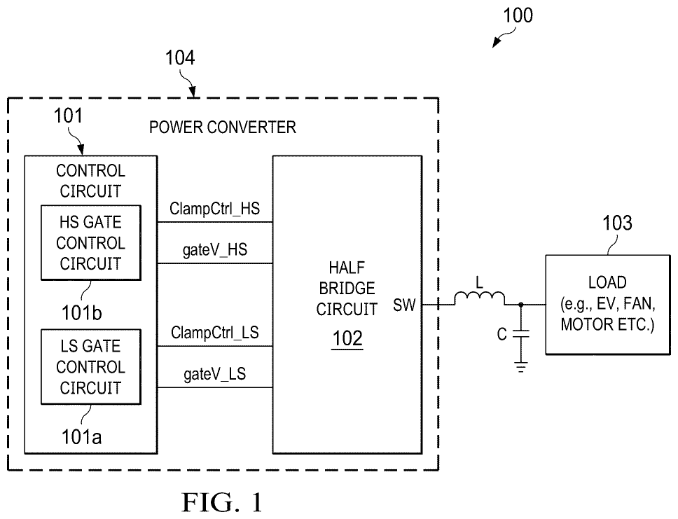

FIG. 1 is a schematic illustrating a system 100 where a power converter has a control circuit coupled to a half bridge circuit, in accordance with at least one example. In at least one example, system 100 comprises a control circuit 101, a half bridge circuit 102, an inductor L, a capacitor C, and a load 103. Control circuit 101 and half bridge circuit 102 are part of a power converter 104. Power converter 104 can be any suitable converter such as a buck, a boost, or a buck-boost power converter. In at least one example, control circuit 101 implements an on-state gate-source voltage limit circuit and an on-state gate current regulation circuit for GaN FETs for half bridge circuit 102. Load 103 can be any suitable load such as an electric vehicle (EV), a fan, a motor, etc.

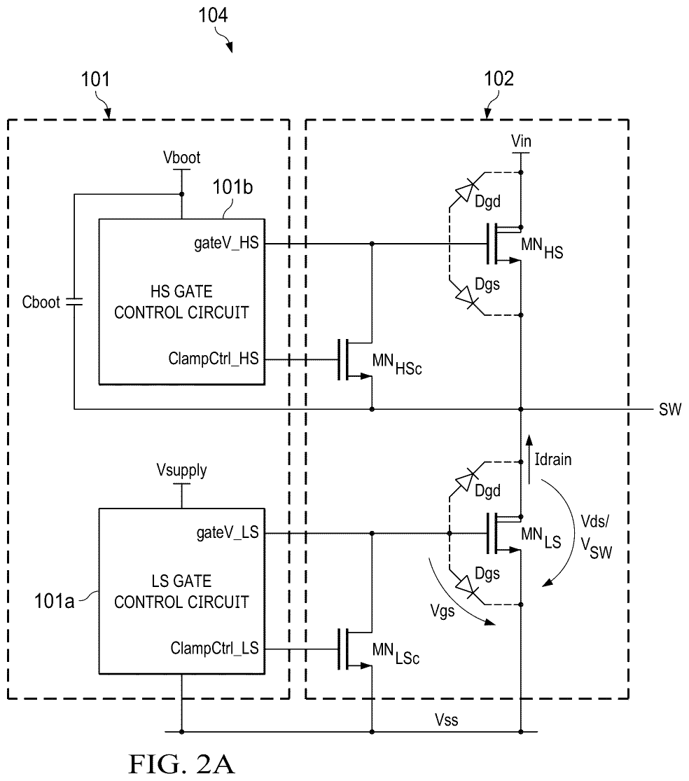

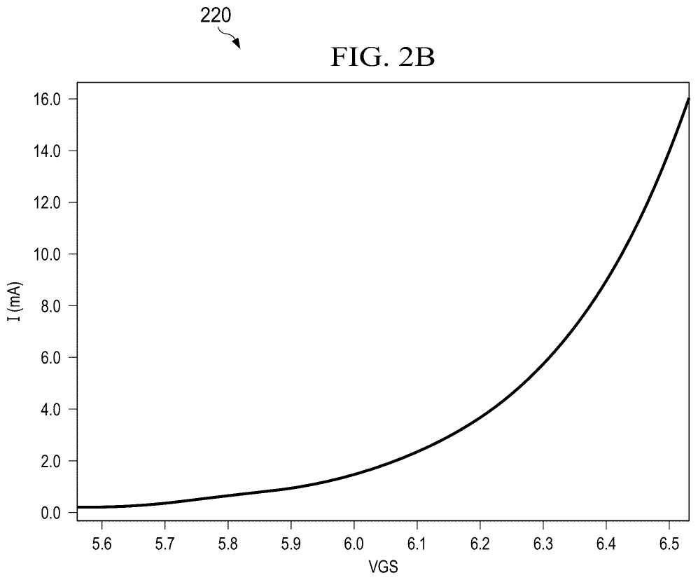

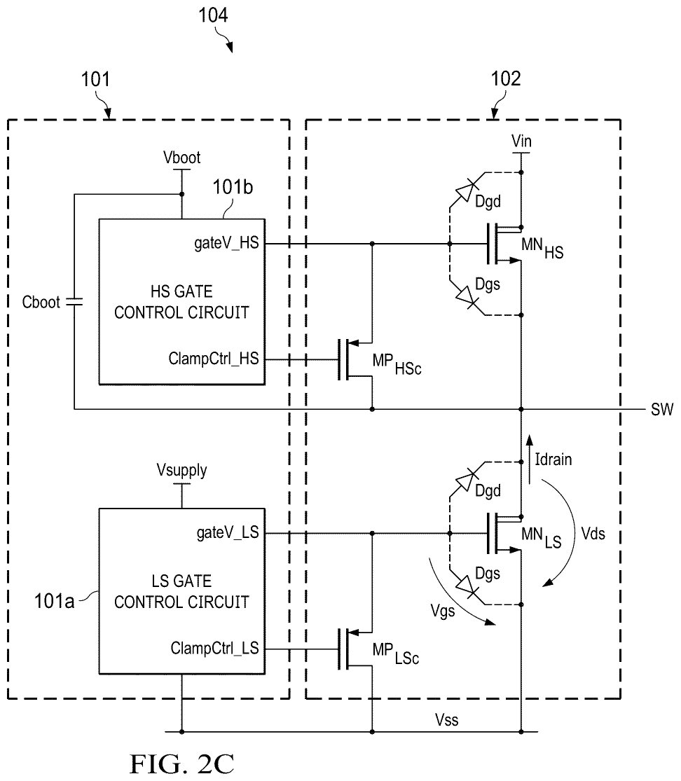

In at least one example, as to be shown in FIGS. 2A and 2B, control circuit 101 includes a low-side (LS) gate control circuit 101a and a high-side (HS) gate control circuit 101b. In at least one example, LS gate control circuit 101a, together with a LS clamp/voltage limit circuit, can implement a first gate driver that can maintain an on-state gate-source voltage for a low-side GaN FET switch of half bridge circuit 102 to be at or below a voltage threshold (e.g., at 6V), and maintain an on-state current to the gate of the low-side GaN FET switch to or below a current threshold. In at least one example, HS gate control circuit 101b, together with a HS clamp/voltage limit circuit, can implement a second gate driver that can maintain an on-state gate-source voltage for a high-side GaN FET switch of half bridge circuit 102 to be at or below a voltage threshold (e.g., at 6V), and maintain an on-state current to the gate of the high-side GaN FET switch to or below the current threshold. The low-side and high-side GaN FET switches are coupled via switching node SW. The low-side and high-side GaN FET switches are coupled to load 103 via the switching node SW, inductor L, and capacitor C.

In at least one example, each gate driver of control circuit 101 includes a pull-up circuit realized as a current source, which provides a gate current to pull up the gate-source voltage of the high-side/low-side switch, and the gate current can be limited to a maximum allowable quiescent current. Each gate driver also includes the clamp circuit as a pull-down circuit realized as a current sink to clamp the gate voltage to be at or below the voltage threshold, by sinking away some of the gate current. In at least one example, control circuit 101 monitors gate-source voltages gateV_LS and gateV_HS of the low-side and high-side GaN FET switches, respectively, and compares it with respective reference voltages. Based on the comparison, control circuit 101 asserts or de-asserts clamp signals ClampCtrl_LS and ClampCtrl_HS to clamp/limit the gate voltages of the low-side and high-side GaN FET switches, respectively, using the clamp/pull down circuits. In some examples, each gate driver of control circuit 101 can be an auxiliary gate driver, and system 100 may include a main gate driver to drive each of the high-side and low-side switches. The main gate driver can pull up the high-side/low-side switch gate-source voltage to a first voltage, and then the auxiliary gate driver of control circuit 101 can further pull up and maintain the on-state gate-source voltage of the high-side/low-side switch at a second voltage and can provide additional gate current if needed. If the main driver provides sufficient gate current, and during the off-state of the high-side or low-side switch, the auxiliary gate driver can provide zero gate current to the switch.

In at least one example, the gate currents to the gates of the GaN FET switches are restricted to defined values (e.g., 0.5 mA) so a maximum quiescent current can be maintained, and the gates are protected from overvoltage. In at least one example, first and second pull-down/clamp circuits are implemented, which become active by the clamp signals in scenarios with low GaN gate leakage (e.g., due to process variation, low temperature, etc.). If the gate-source voltage of the GaN FET switch is at or exceeds a desired value (e.g., 6V), the first/second pull-down circuit can reduce the gate current provided by the respective pull-up circuit by sinking away some of the gate current. In at least one example, the first and second pull-down circuits comprise a respective clamp device (e.g., p-type or n n-type device) that can sink some of the current directly to the source of the GaN FET switch in case the gate-source voltage exceeds the desired set-value.

FIG. 2A is a schematic illustrating power converter 104 with control circuits and n-type clamp circuits for high-side and low-side switches, respectively, in accordance with at least one example. FIG. 2B is a plot 220 illustrating an exponential function of gate-to-source voltage (VGS) versus current for a GaN transistor used for high-side and low-side switches. In at least one example, half bridge circuit 102 comprises a low-side GaN FET MN_{LS} and a high-side GaN FET MN_{HS} coupled in series. The source of high-side GaN FET MN_{HS} and the drain of the low-side GaN FET MN_{LS} are coupled to switching node SW, which is coupled to load 103 via inductor L and capacitor C. The low-side GaN FET MN_{LS} turns on when its VGS is greater than a threshold voltage. This gate-source voltage VGS is maintained at 5-6V for an enhancement mode (e-mode) GaN FET, for example. As GaN FET technologies advance, some technologies have no insulated gate (e.g., no gate oxide) and have gate diodes between gate and drain (Dgd) and gate and source (Dgs). These gate diodes have exponential gate-current over gate-voltage characteristics as illustrated in plot 220. At 6V VGS, gate current of 1.5 mA may be desired for the GaN FETs, for instance. For bootstrap supplied high-side GaN FET MN_{HS}, the gate-current is to be limited to avoid the voltage dropping below a lockout voltage, especially for long high-side-on duty cycles. If power converter 104 is configured as a boost converter, the input supply Vin coupled to the high-side GaN FET MN_{HS} can become an output supply and reverse drain current (e.g., third quadrant operation) flows through switching node SW and the high-side GaN FET MN_{HS} towards the output supply. In the absence of control circuit 101, the reverse drain current causes an IR drop that results in a gate-to-source voltage of greater than 6.5V and a corresponding current of 15 mA (which is 10x of the current when VGS is 6V), as indicated by plot 200. This excess current and increase in gate-to-drain voltage can cause the GaN FET to fail. Control circuit 101 of some examples provides a constant current to the gates of the GaN FETs and clamps any overvoltage between the gate and drain terminals of the GaN FETs.

In at least one example, power converter 104 comprises a first voltage clamp device MN_{LSc} coupled between the gate and source terminals of the low-side GaN FET MN_{LS} and controllable by ClampCtrl_LS provided by LS gate control circuit 101a. LS gate control circuit 101a monitors gate-source voltage gateV_LS of the low-side GaN FET MN_{LS} and turns the voltage clamp device MN_{LSc} on and off based on the gate-source voltage gateV_LS being above or below a threshold voltage Vref (with respect to the source voltage of low-side GaN FET MN_{LS}, which can be a ground voltage). This allows LS gate control circuit 101a to maintain the gate-source voltage to keep the low-side GaN FET MN_{LS} on and avoid a large gate current from a higher gate-source voltage. In at least one example, LS gate control circuit 101a includes a current source to provide a drive current (e.g., 0.5 mA) to the gate of the low-side GaN FET MN_{LS} so a maximum quiescent current can be maintained for the low-side GaN FET MN_{LS} when it is turned on.

In at least one example, HS gate control circuit 101b controls a voltage clamp device MN_{HSc} coupled between a gate terminal and a source terminal of the high-side GaN FET MN_{HS}. Here, the high-side GaN FET MN_{HS} is coupled to an input supply Vin while HS gate control circuit 101b is powered by the bootstrap voltage supply Vboot provided by a bootstrap capacitor Vboot coupled between Vboot power supply rail and switching node SW. HS gate control circuit 101b monitors gate-source voltage gateV_HS of the high-side GaN FET MN_{HS} and turns the voltage clamp device MIN_{HSc} on and off based on the gate-source voltage gateV_HS being above or below a threshold voltage Vref (with respect to the source voltage of high-side GaN FET MN_{LS}, which can be the voltage at the switching node SW, Vsw). This allows HS gate control circuit 101b to maintain the gate-source voltage of the high-side GaN FET MN_{HS} to avoid large gate current when, for example, the gate-source voltage is at 6.5V instead of 6V. In at least one example, HS gate control circuit 101b provides a constant drive current (e.g., 0.5 mA) to the gate of the high-side GaN FET MN_{HS} so a maximum quiescent current can be maintained for the high-side GaN FET MN_{bs} when it is turned on.

FIG. 2C is a schematic illustrating power converter 104 with control circuits and p-type clamps MP_{HSC} and MP_{LSC} for high-side and low-side GaN FET switches, respectively, in accordance with at least one example. Functionally, the power converter of FIG. 2C is similar in function to the power converter of FIG. 2A.

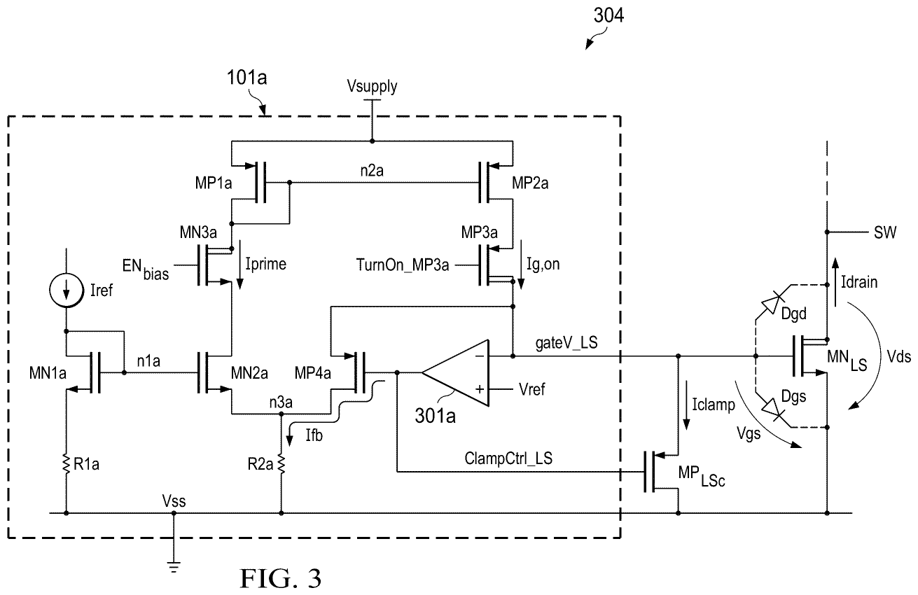

FIG. 3 is a schematic illustrating a first portion 304 of power converter 104 with p-type clamp for the low-side switch, in accordance with at least one example. In at least one example, the first voltage limit circuit of control circuit 101a comprises comparator 301a and a p-type clamp MP_{LSc}. Comparator 301a has a first input terminal coupled to the gate terminal gateV_LS of the low-side GaN FET MN_{LS} and a second input terminal coupled to a reference Vref (e.g., 6V). An output ClampCtrl_LS of comparator 301a is coupled to a gate of p-type clamp MP_{LSc}, which has source and drain terminals coupled to the gate terminal gateV_LS and a ground supply rail Vss. Comparator 301a compares the gate voltage on the gate terminal gateV_LS against the reference voltage Vref, with both voltages with reference to the source voltage of MN_{LS} (e.g., Vss) and turns on the clamp MPLSc via ClampCtrl_LS if the gate voltage on the gate terminal gateV_LS is above the reference voltage Vref. If the gate voltage on the gate terminal gateV_LS is below the reference voltage Vref, the clamp MP_{LSc} remains disabled.

In at least one example, control circuit 101a comprises a current source including n-type transistors MN1a, MN2a, and MN3a, p-type transistor MP1a, MP2a, MP3a, and MP4a, and resistors R1a and R2a. In at least one example, transistors MN1a and MN2a form a first current mirror with the gates (node n1a) of MN1a and MN2a coupled and drain of transistor MN1a coupled to node n1a forming a diode-connected transistor. A reference current circuit provides reference current Iref which is multiplied and adjusted to provide a constant drive current to the gate of the low-side GaN FET MN_{LS}. Current multiplication in transistor MN2a is determined by the ratio of sizes of transistors MN1a and MN2a, and/or ratio of resistances of resistors R1 and R2a. For example, transistor MN2a is 8 to 16 times larger than transistor MN1a to have 8 to 16 times more current than current through transistor MN1a.

In at least one example, a second current mirror is coupled to the first current mirror and sets up the current for the gate of the low-side GaN FET MN_{LS}. The second current mirror comprises p-type transistors MP1a and MP2a with the gates (node n2a) of MP1a and MP2a coupled, and drain of transistor MP1a coupled to node n2a. The source terminals of p-type transistors MP1a and MP2a are coupled to a supply rail Vsupply (e.g., 10V to 20V). Current multiplication in transistor MP2a is determined by the ratio of sizes of transistors MP1a and MP2a. For example, transistor MP2a is 5 to 20 times larger than transistor MP1a to have 5 to 20 times more current than current through transistor MPa.

In at least one example, to protect reliability of low-voltage transistors MP1a and MP2a, which may be CMOS transistors that can operate at 5V, high-voltage transistors MN3a and MP3a are coupled in series with p-type transistors MP1a and MP2a, respectively. For instance, FETs MN3a and MP3a are one of 12V, 15V, 20V, 30V, or 40V transistors that can operate and tolerate voltages of 12V, 15V, 20V, 30V, or 40V. In at least one example, currents Iprime and Ig,on through MP1a and MP2a, respectively, are discontinued by disabling transistors MN3a and MP3a via controls EN_{bias} and TurnON_MP3a, respectively.

Here, EN_{bias} is a logic signal, that is provided by a controller of power converter 104, which may be integrated on the same silicon chip with a gate driver or may be an external controller. If EN_{bias} is logic low level (e.g., like a local reference potential VSS), power converter 104 is in “shutdown” mode where it consumes very little power. While EN_{bias} is low, the gate driver may not be able to turn-on the GaN FET MN_{LS} and most functions of power converter 104 are disabled. If EN_{bias} is logic high level (e.g., 5V higher than VSS), power converter 104 is biased and active and can act on other control signals such as turning on GaN FET MN_{LS}. EN_{bias} activates the input branch of the current mirror(s).

In at least one example, current Ig,on through transistor MP2a maintains the gate voltage on the gate terminal gateV_LS to be at the reference voltage level Vref to avoid a large gate current when, for example, the gate-source voltage increases above 6V. In at least one example, transistor MP2a provides a constant drive current Ig,on (e.g., 0.5 mA) to the gate of the low-side GaN FET MN_{LS} so a maximum quiescent current can be maintained for the low-side GaN FET MN_{LS} when it is turned on.

In at least one example, an additional current path is provided for the gate current and this current path through p-type transistor MP4a is enabled by the clamp MPLSc turning on. Transistor MP4a is coupled to the gate of the low-side GaN FET MN_{LS} and node n3a, which in turn is coupled to resistor R2a. This additional current path provides current Ifb through transistor MP4a and reduces current Iprime, which in turn reduces current Ig,on. In at least one example, the current Ig,on is reduced to a non-zero value to save power. In at least one example, the current Ig,on can be reduced to a zero value in steady state if, for example, the GaN FET MN_{LS} is in the off-state, the on-state gate leakage current in the GaN FET MN_{LS} is below a threshold, and/or if control circuit 101a is an auxiliary gate driver, and a main gate driver also drives the GaN FET MN_{LS} and provides sufficient gate current to cover the on-state gate leakage current.

In at least one example, the low-side GaN FET MN_{LS} is controlled by a controller of power converter 104 which decides when to turn on the low-side GaN FET MN_{LS} based on load current, voltage, and power controller specifications. In at least one example, the controller generates a pulse width modulation (PWM) signal used to turn-on gate of the low-side GaN FET MN_{LS}. When the low-side GaN FET MN_{LS} is turned on, Ig,on with a pre-set current is provided to the gate of the low-side GaN FET MN_{LS}. The gate voltage gateV_LS is sensed by comparator 301a (or an amplifier) and controlled by sinking the current (Iclamp) if VGS exceeds Vref. When the low-side GaN FET MN_{LS} is turned on, the controller turns on transistor MP3a. For example, the controller sets control TurnOn_MP3a to negative supply voltage (−5V) to turn on transistor MP3a. Current Iref x X as Ig,on is provided to the gate of the low-side GaN FET MN_{LS}, where ‘X’ is a multiplying factor and can be configured by current mirrors. In at least one example, transistors MN2a and/or MP2a have variable or tunable width to change the multiplying factor X. For instance, software or hardware (e.g., fuses or registers) may be used to add or subtract from a total active width of transistors MN2a and/or MP2a by enabling or disabling transistors that are coupled parallel to transistors MN2a and/or MP2a. In at least one example, depending on the size of the low-side GaN FET MN_{LS}, the multiplying factor X can be adjusted allowing one silicon design of LS gate control circuit 101a to be used for various sizes of low-side GaN FETs. In at least one example, transistors MN2a and/or MP2a comprise several transistors in parallel that are binary weighted or thermometer weighted.

As the low-side GaN FET MN_{LS} turns on, the VGS of the low-side GaN FET MN_{LS} rises. Comparator 301a continues to monitor the voltage on gateV_LS and once the voltage on gateV_LS exceeds Vref, the output ClampCtrl_LS of comparator 301a goes low to turn on clamp MPLSc. Clamp transistor MPLSc discharges gateV_LS as indicated by flow of current Iclamp. When the clamp transistor MPLSc is on, current Ig,on from the current source also sinks to ground. The current drained by the clamp transistor MPLSc can also be used in an additional voltage loop to adjust or reduce the current Ig,on in steady state to save power. In at least one example, ClampCtrl_LS is used to turn on transistor MP4a when the clamp transistor MPLSc is on. This allows current Iprime to reduce because current Ifb flows through transistor MP4a. As current Iprime reduces, current Ig,on reduces, which saves power and prevents overshoot of VGS of the low-side GaN FET MN_{LS} when the clamp transistor MPLSc is on. In at least one example, current Ig,on is reduced to a non-zero value to save power. In at least one example, current Ig,on is reduced to a zero value.

In at least one example, current Ifb ramps up with some delay and current Iprime and subsequently current Ig,on reduce. After a steady state is achieved and the voltage on gateV_LS sets back to 6V, current Iclamp is no longer needed, and current Ig,on is reduced to a value where it provides the exact gate current (e.g., 0.5 mA) to maintain VGS=Vref. As discussed herein, independent of VGS, the gate current to the gate of low-side GaN FET MN_{LS} is limited to Ig,on=Iref*x, where x=40 . . . 320, in accordance with at least one example. In at least one example, for quick turn-on of the low-side GaN FET MN_{LS}, a pre-charge with higher current can be added. The pre-charge current can be turned off based on fixed or adaptive timing, for instance. In at least one example, for shorter turn-on time (e.g., faster ramp-up of VGS), a second current source with higher current for turn-on can be added, which is shut-off before VGS reaches Vref.

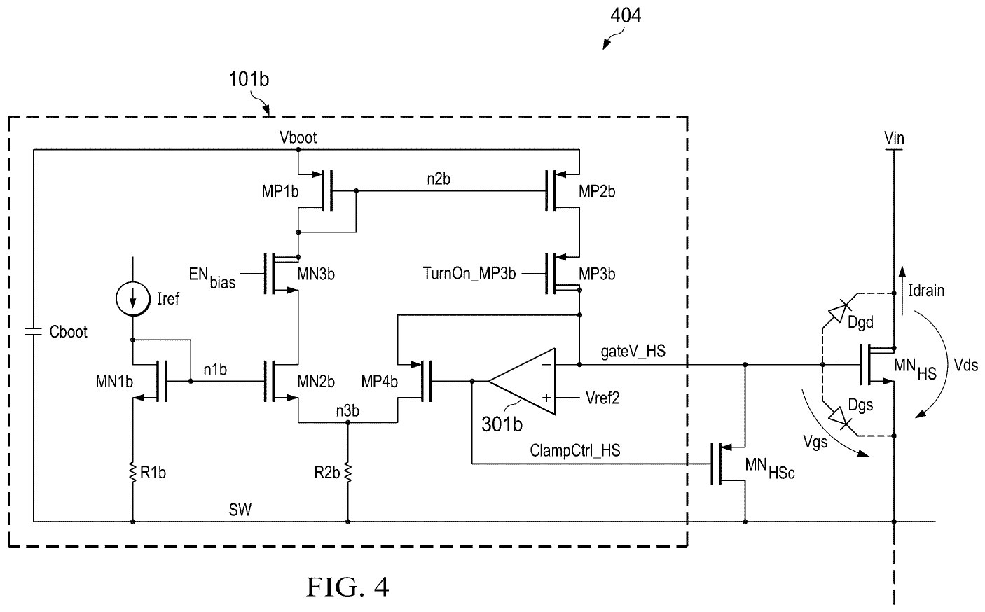

FIG. 4 is a schematic illustrating a second portion 404 of control circuit 101 with p-type clamp for the high-side switch, in accordance with at least one example. Functionally, the control circuit of FIG. 3 is similar to the control circuit of FIG. 4 and is configured to operate for high-side switch. In at least one example, the second voltage limit circuit of control circuit 104b comprises comparator 301b (or amplifier) and a p-type clamp MP_{HSc}. Comparator 301b has a first input terminal coupled to the gate terminal gateV_HS of the high-side GaN FET MN_{HS} and a second input terminal coupled to a second reference Vref2 (e.g., 6V). An output ClampCtrl_HS of comparator 301b is coupled to a gate of p-type clamp MP_{HSc}, which has source and drain terminals coupled to the gate terminal gateV_HS and the switching node SW. Comparator 301b compares the gate voltage on the gate terminal gateV_HS against the second reference voltage

Vref, with both voltages with reference to the source voltage of MN_{HS} (e.g., Vsw) and turns on the clamp MP_{HSc} via ClampCtrl_HS if the gate voltage on the gate terminal gateV_HS is above the second reference voltage Vref. If the gate voltage on the gate terminal gateV_HS is below the second reference voltage Vref2, the clamp MP_{HSc} remains disabled.

In at least one example, control circuit 101b comprises a current source including n-type transistors MN1b, MN2b, and MN3b, p-type transistor MP1b, MP2b, MP3b, and MP4b, and resistors R1b and R2b. In at least one example, transistors MN1b and MN2b form a third current mirror with the gates (node n1b) of MN1b and MN2b coupled and drain of transistor MN1b coupled to node n1a forming a diode-connected transistor. A reference current circuit provides reference current Iref which is multiplied and adjusted to provide a constant current to the gate of the high-side GaN FET MN_{HS}. Current multiplication in transistor MN2b is determined by the ratio of sizes of transistors MN1b and MN2b, and/or ratio of resistances of resistors R1b and R2a. For example, transistor MN2b is 8 to 16 times larger than transistor MN1b to have 8 to 16 times more current than current through transistor MN1a.

In at least one example, a fourth current mirror is coupled to the third current mirror and sets up the current for the gate of the high-side GaN FET MN_{HS}. The fourth current mirror comprises p-type transistors MP1b and MP2b with the gates (node n2b) of MP1b and MP2b coupled and drain of transistor MP1b coupled to node n2b. The source terminals of p-type transistors MP1b and MP2b are coupled to the boot supply rail Vboot. Boot supply rail Vboot is coupled to the fourth current mirror. The current multiplication in transistor MP2b is determined by the ratio of sizes of transistors MP1b and MP2b. For example, transistor MP2b is 5 to 20 times larger than transistor MP1b to have 5 to 20 times more current than current through transistor MP1b.

In at least one example, to protect reliability of low-voltage transistors MP1b and MP2b, which may be CMOS transistors that can operate at 5V, high-voltage transistors MN3b and MP3b are coupled in series with p-type transistors MP1b and MP2b, respectively. For instance, FETs MN3b and MP3b are one of 12V, 15V, 20V, 30V, or 40V transistors that can operate and tolerate voltages of 12V, 15V, 20V, 30V, or 40V. In at least one example, currents Iprime and Ig,on through MP1b and MP2b, respectively, are discontinued by disabling transistors MN3b and MP3b via controls EN_{bias} and TurnON_MP3b, respectively. If EN_{bias} is logic low level (e.g., like a local reference potential Vsw), power converter 104 is in “shutdown” mode where it consumes very little power. While EN_{bias} is low, the gate driver may not be able to turn-on the GaN FET MN_{HS} and most functions of power converter 104 are disabled. If EN_{bias} is logic high level (e.g., 5V higher than Vsw), power converter 104 is biased and active and can act on other control signals such as turning on GaN FET MN_{HS}. EN_{bias} activates the input branch of the current mirror(s).

In at least one example, current Ig,on through transistor MP2b maintains the gate voltage on the gate terminal gateV_HS to be at the reference voltage level Vref to avoid a large gate current t when the gate-source voltage increases above 6V. In at least one example, transistor MP2b provides a constant drive current Ig,on (e.g., 0.5 mA) to the gate of the high-side GaN FET MN_{HS} so a maximum quiescent current can be maintained for the high-side GaN FET MN_{HS} when it is turned on.

In at least one example, an additional current path is provided for the gate current and this current path through p-type transistor MP4b is enabled by the clamp MP_{HSc} turning on. Transistor MP4b is coupled to the gate of the high-side GaN FET MN_{HS} and node n3b, which in turn is coupled to resistor R2b. This additional current path provides current Ifb through transistor MP4b and reduces current Iprime, which in turn reduces current Ig,on. In at least one example, current Ig,on is reduced to a non-zero value to save power. In at least one example, current Ig,on is reduced to a zero value if, for example, the GaN FET MN_{HS} is in the off-state, the on-state gate leakage current in the GaN FET MN_{HS} is below a threshold, and/or if control circuit 101b is an auxiliary gate driver, and a main gate driver also drives the GaN FET MN_{HS} and provides sufficient gate current to cover the on-state gate leakage current.

In at least one example, the high-side GaN FET MN_{HS} is controlled by the controller of power converter 104 which decides when to turn on the high-side GaN FET MN_{HS} based on load current, voltage, and power controller specifications. In at least one example, the controller generates a PWM signal used to turn-on the gate of the high-side GaN FET MN_{HS}. When the high-side GaN FET MN_{HS} is turned on, current Ig,on with a pre-set current is provided to the gate of the high-side GaN FET MN_{HS}. The gate voltage gateV_HS is sensed by comparator 301b and controlled by sinking the current (Iclamp) if VGS exceeds Vref2. When the high-side GaN FET MN_{HS} is turned on, the controller turns on transistor MP3b. For example, the controller sets control TurnOn_MP3b to negative supply voltage −5V) to turn on transistor MP3b. Current Iref x X as Ig,on is provided to the gate of the high-side GaN FET MN_{HS}, where ‘X’ is a multiplying factor and can be configured by current mirrors. In at least one example, transistors MN2b and/or MP2b have variable or tunable width to change the multiplying factor X. For instance, software or hardware (e.g., fuses or registers) may be used to add to or substrate from a total active width of transistors MN2b and/or MP2b by enabling or disabling transistors that are coupled parallel to transistors MN2b and/or MP2b. In at least one example, depending on the size of the high-side GaN FET MN_{HS}, the multiplying factor X can be adjusted allowing one silicon design of HS gate control circuit 101b to be used for various sizes of high-side GaN FETs. In at least one example, transistors MN2b and/or MP2b comprise several transistors in parallel that are binary weighted or thermometer weighted.

As the high-side GaN FET MN_{HS} turns on, the VGS of the high-side GaN FET MN_{HS} rises. Comparator 301b continues to monitor the voltage on gateV_HS and once the voltage on gateV_HS exceeds Vref2, the output ClampCtrl_HS of comparator 301b goes low to turn on clamp MP_{HSc}. Clamp transistor MP_{HSc} discharges gateV_HS as indicated by flow of current Iclamp. When the clamp transistor MP_{HSc} is on, current Ig,on from the current source also flows to switching node SW. The current drained by the clamp transistor MP_{HSc} can also be used in an additional voltage loop to adjust or reduce the current Ig,on in steady state to save power. In at least one example, ClampCtrl_HS is used to turn on transistor MP4b when the clamp transistor MP_{HSc} is on. This allows current Iprime to reduce because current Ifb flows through transistor MP4b. As current Iprime reduces, current Ig,on reduces, which saves power and prevents overshoot of VGS of the high-side GaN FET MN_{HS} when the clamp transistor MP_{HSc} is on. In at least one example, current Ig,on is reduced to a non-zero value to save power. In at least one example, current Ig,on is reduced to a zero value. In at least one example, the current Ig,on is reduced to a zero value if, for example, the GaN FET MN_{HS} is in the off-state, the on-state gate leakage current in the GaN FET MN_{HS} is below a threshold, and/or if control circuit 101b is an auxiliary gate driver, and a main gate driver also drives the GaN FET MN_{HS} and provides sufficient gate current to cover the on-state gate leakage current.

In at least one example, current Ifb ramps up with some delay and current Iprime and subsequently current Ig,on reduce. After a steady state is achieved and the voltage on gateV_HS sets back to 6V, current Iclamp is no longer needed, and current Ig,on is reduced to a value where it provides the exact gate drive current (e.g., 0.5 mA) to maintain VGS=Vref. As discussed herein, independent of VGS, the gate current to the gate of high-side GaN FET MN_{HS} is limited to Ig,on=Iref*x, where x=40 . . . 320, in accordance with at least one example. In at least one example, for quick turn-on of the high-side GaN FET MN_{HS}, a pre-charge with higher current can be added. The pre-charge current can be turned off based on fixed or adaptive timing, for instance. In at least one example, for shorter turn-on time (e.g., faster ramp-up of VGS), a second current source with higher current for turn-on can be added, which is shut-off before VGS reaches Vref2.

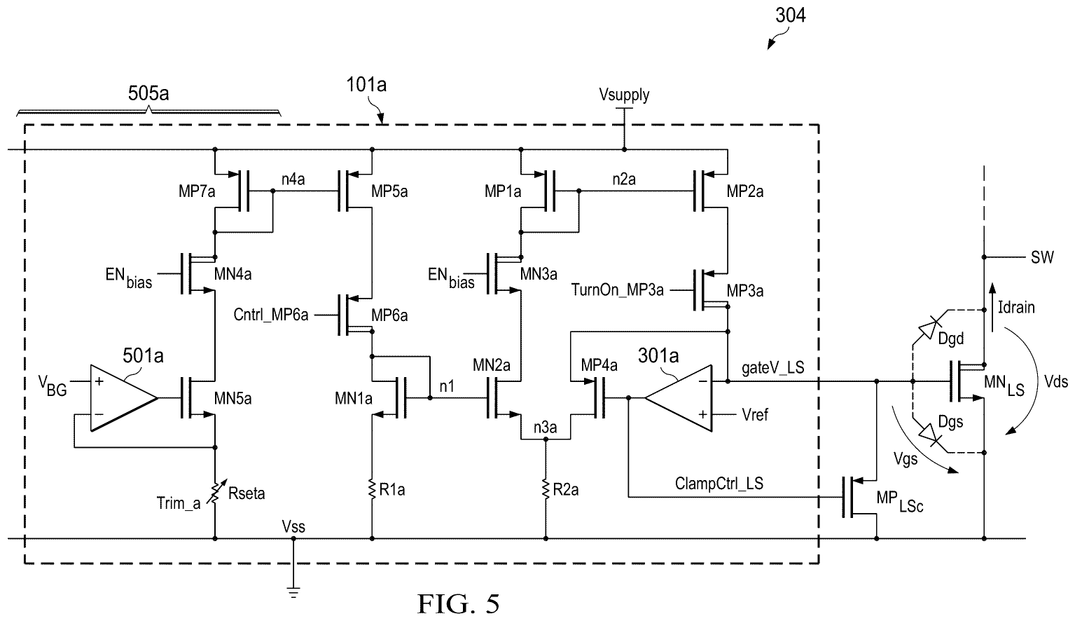

FIG. 5 is a schematic illustrating the portion of the control circuit with p-type clamp and associated current reference circuit for the low-side switch, in accordance with at least one example. Here, portion 304 illustrates an additional portion 504a which includes a first reference generating circuit. In at least one example, the first reference generating circuit comprises an amplifier 501a, n-type transistors MN4a and MN5a, p-type transistors MP5a, MP6a, and MP7a, and adjustable or trimmable resistor Rset.

In at least one example, a fifth current mirror is coupled to the first current mirror and sets up Iref. The fifth current mirror comprises p-type transistors MP5a and MP7a with the gates (node n4a) of MP7a and MP5a coupled and drain of transistor MP7a coupled to node n4a. The source terminals of p-type transistors MP7a and MP5a are coupled to supply rail Vsupply. Current multiplication in transistor MP5a is determined by the ratio of sizes of transistors MP5a and MP7a. In at least one example, to protect reliability of low-voltage transistors MP7a and MP5a, which may be CMOS transistors that can operate at 5V, high-voltage transistors MN4a and MP6a are coupled in series with p-type transistors MP7a and MP5a, respectively. For instance, FETs MN4a and MP6a are one of 12V, 15V, 20V, 30V, or 40V transistors that can operate and tolerate voltages of 12V, 15V, 20V, 30V, or 40V. Here, transistor MN4a is controlled by EN_{bias} while transistor MP6a is controlled by Ctrl_MP6a. Ctrl_MP6a signal is generated in a gate driver logic as a reaction to the controller of power converter 104 requesting a turn-on of the GaN FET MP_{LS}. Ctrl_MP6a propagates in a floating domain between Vsupply +5V and Vsupply −5V. When Ctrl MP6a is low (e.g., at Vsupply −5V), Ctrl_MP6a enables the output branch of the current mirrors and is typically in sync with TurnOn_MP3a.

Amplifier 501a biases transistor MN5a such that the voltages at inputs V_{GB} and source of transistor MN5a are substantially equal, where the source of transistor MN5a is coupled to ground via adjustable resistor Rseta. V_{GB} is a bandgap voltage (e.g., 1.22V) generated from a bandgap circuit (not shown). The resistance of resistor Rseta can be adjusted to adjust Iref by a Trim_a signal that can add or subtract resistors in parallel to change the overall resistance.

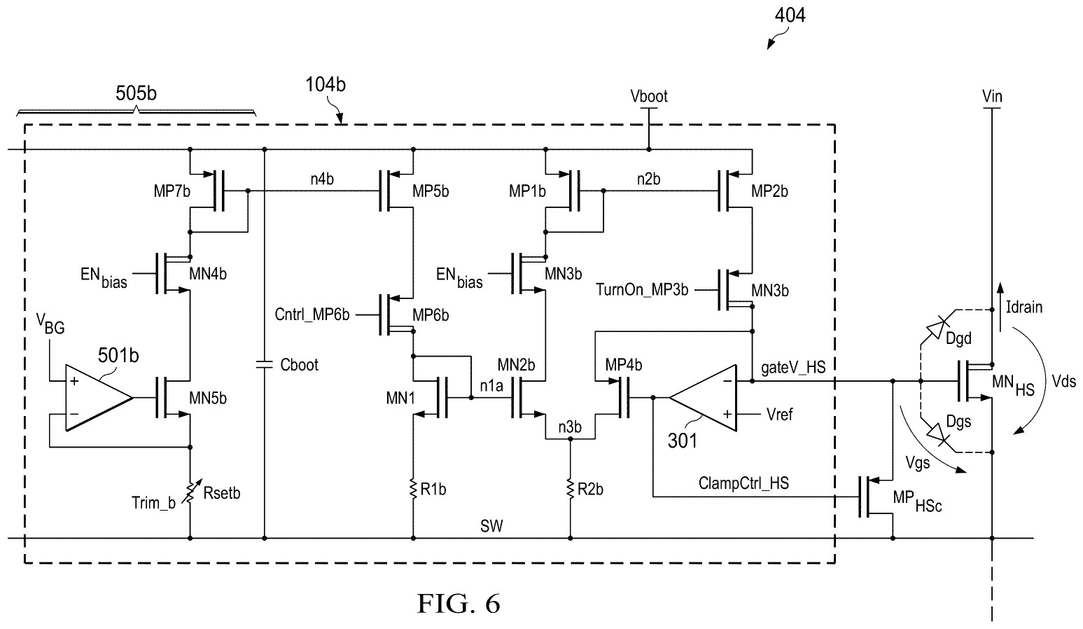

FIG. 6 is a schematic illustrating the portion of the control circuit with p-type clamp and associated current reference circuit for the high-side switch, in accordance with at least one example. Here, portion 304 illustrates an additional portion 505b which includes a second reference generating circuit. In at least one example, the second reference generating circuit comprises an amplifier 501b, n-type transistors MN4b and MN5b, p-type transistors MP5b, MP6b, and MP7b, and adjustable or trimmable resistor Rset.

In at least one example, a sixth current mirror is coupled to the third current mirror and sets up Iref. The third current mirror comprises p-type transistors MP5b and MP7b with the gates (node n4b) of MP7b and MP5b coupled and drain of transistor MP7b coupled to node n4b. The source terminals of p-type transistors MP7b and MP5b are coupled to boot supply rail Vboot. Current multiplication in transistor MP5b is determined by the ratio of sizes of transistors MP5b and MP7b. In at least one example, to protect reliability of low-voltage transistors MP7b and MP5b, which may be CMOS transistors that can operate at 5V, high-voltage transistors MN4b and MP6b are coupled in series with p-type transistors MP7b and MP5b, respectively. For instance, FETs MN4b and MP6b are one of 12V, 15V, 20V, 30V, or 40V transistors that can operate and tolerate voltages of 12V, 15V, 20V, 30V, or 40V. Here, transistor MN4b is controlled by EN_{bias} while transistor MP6b is controlled by Ctrl_MP6b. Ctrl MP6b signal is generated in a gate driver logic as a reaction to the controller of power converter 104 requesting a turn-on of the GaN FET MP_{HS}. Ctrl MP6b propagates in a floating domain between Vsupply +5V and Vsupply −5V. When Ctrl_MP6b is low (e.g., at Vsupply −5V), Ctrl_MP6b enables the output branch of the current mirrors and is typically in sync with TurnOn_MP3b.

Amplifier 501b biases transistor MN5b such that the voltages at inputs V_{GB} and source of transistor MN5b are substantially equal, where the source of transistor MN5a is coupled to switching node SW via adjustable resistor Rsetb. V_{GB} is a bandgap voltage generated from a bandgap circuit. The resistance of resistor Rsetb can be adjusted to adjust Iref by a Trim_b signal that can add or subtract resistors in parallel to change the overall resistance.

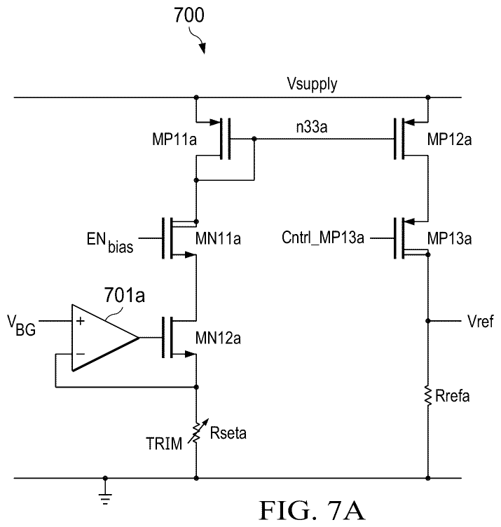

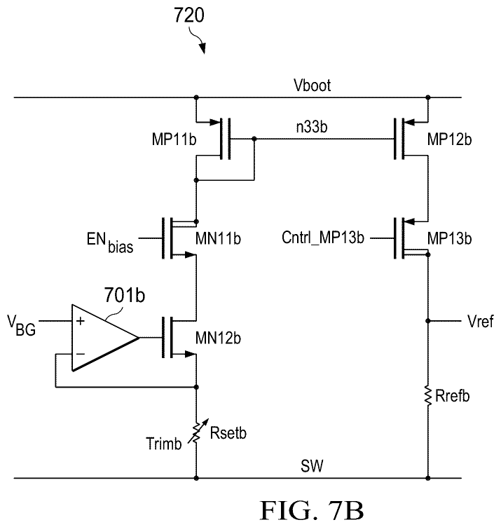

FIGS. 7A-B are schematics illustrating reference voltage generation circuits 700 and 720 for the control circuits 101a and 101b, respectively, in accordance with some examples. In at least one example, reference voltage generation circuit 700 comprises a current mirror that includes p-type transistors MP11a and MP12a with the gates (node n33a) of MP11a and MP12a coupled and drain of transistor MP11a coupled to node n33a. The source terminals of p-type transistors MP11a and MP12a are coupled to supply rail Vsupply. Current multiplication in transistor MP12a is determined by the ratio of sizes of transistors MP11a and MP12a.

In at least one example, to protect reliability of low-voltage transistors MP11a and MP12a, which may be CMOS transistors that can operate at 5V, high-voltage transistors MN11a and MP13a are coupled in series with p-type transistors MP11a and MP12a, respectively. For instance, FETs MN11a and MP13a are one of 12V, 15V, 20V, 30V, or 40V transistors that can operate and tolerate voltages of 12V, 15V, 20V, 30V, or 40V. Here, transistor MN11a is controlled by EN_{bias} while transistor MP13a is controlled by Ctrl_MP13a. Ctrl_MP13a signal is generated in a gate driver logic as a reaction to the controller of power converter 104 requesting a turn-on of the GaN FET MP_{LS}. Ctrl_MP13a propagates in a floating domain between Vsupply +5V and Vsupply −5V. When Ctrl_MP13a is low (e.g., at Vsupply −5V), Ctrl_MP13a enables the output branch of the current mirrors.

Amplifier 701a biases transistor MN12a such that the voltages at inputs VGB and source of transistor MN12a are substantially equal, where the source of transistor MN12a is coupled to ground via adjustable resistor Rseta. VGB is a bandgap voltage generated from a bandgap circuit. The resistance of resistor Rsetb can be adjusted to adjust Vref by a Trim_a signal that can add or subtract resistors in parallel to change the overall resistance. The value of Vref is also determined by the ratio of resistances of resistors Rrefa and Rseta, where resistor Rrefa is coupled in series with transistor FET MP13a.

In at least one example, reference voltage generation circuit 720 comprises a current mirror that comprises p-type transistors MP11b and MP12b with the gates (node n33b) of MP11b and MP12b coupled and drain of transistor MP11b coupled to node n33b. The source terminals of p-type transistors MP11b and MP12b are coupled to boot supply rail Vboot. Current multiplication in transistor MP12b is determined by the ratio of sizes of transistors MP11b and MP12b.

In at least one example, to protect reliability of low-voltage transistors MP11b and MP12b, which may be CMOS transistors that can operate at 5V, high-voltage transistors MN11b and MP13b are coupled in series with p-type transistors MP11b and MP12b, respectively. For instance, FETs MN11b and MP13b are one of 12V, 15V, 20V, 30V, or 40V transistors that can operate and tolerate voltages of 12V, 15V, 20V, 30V, or 40V. Here, transistor MN11b is controlled by EN_{bias} while transistor MP13b is controlled by Ctrl_MP13b. Ctrl_MP13b signal is generated in a gate driver logic as a reaction to the controller of power converter 104 requesting a turn-on of the GaN FET MP_{HS}. Ctrl_MP13b propagates in a floating domain between Vsupply +5V and Vsupply −5V. When Ctrl_MP13b is low (e.g., at Vsupply −5V), Ctrl_MP13b enables the output branch of the current mirrors.

Amplifier 701b biases transistor MN12a such that the voltages at inputs VGB and source of transistor MN12b are substantially equal, where the source of transistor MN12b is coupled to ground via adjustable resistor Rsetb. The resistance of resistor Rsetb can be adjusted to adjust Vref2 by a Trim_b signal that can add or subtract resistors in parallel to change the overall resistance. The value of Vref2 is also determined by the ratio of resistances of resistors Rrefb and Rsetb, where resistor Rrefb is coupled in series with resistor MP13b.

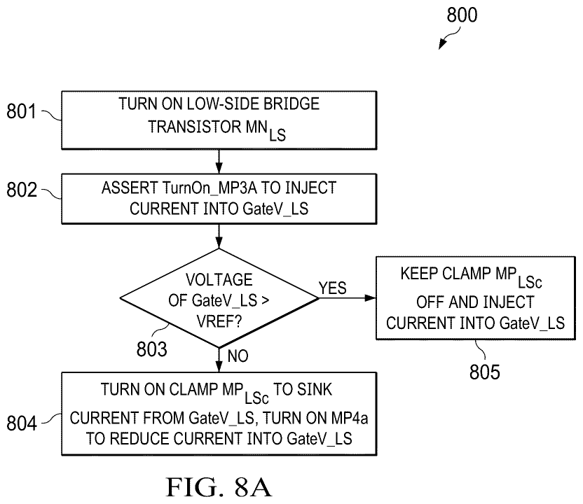

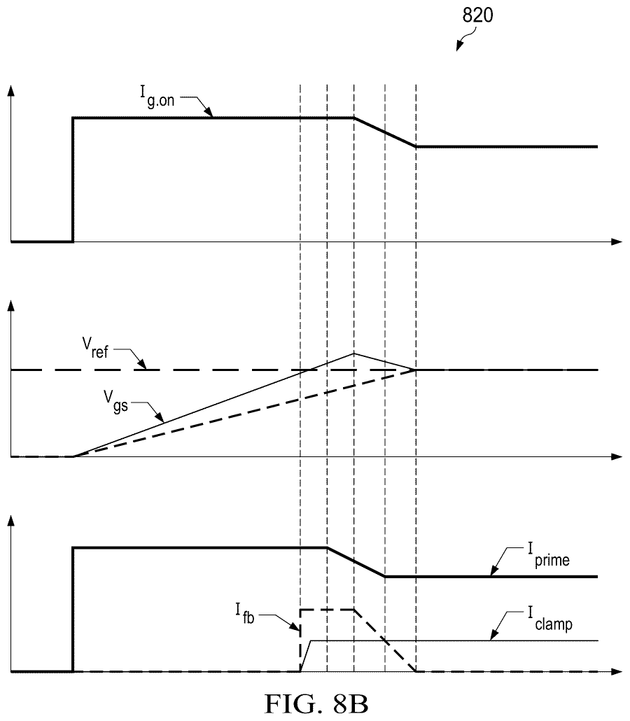

FIGS. 8A-B are a flowchart 800 of a method of driving a transistor and its associated timing diagram 820, respectively, in accordance with at least some examples. Flowchart 800 is illustrated with reference to driving low-side GaN FET MN_{LS} in FIG. 3. The same method is also applicable for driving high-side GaN FET MN_{HS} in FIG. 4. The method comprises injecting a first current (Ig,on) to a control terminal gateV_LS of the low-side GaN FET MN_{LS}. Responsive to a voltage of the control terminal exceeding a threshold Vref, where both the control terminal voltage and the threshold are with reference to the source of the transistor, the method further comprises reducing the first current and sinking a second current Iclamp from the control terminal. In at least one example, responsive to the voltage being at the threshold, the method comprises maintaining the first current Ig,on at a non-zero value. In at least one example, responsive to the voltage being below the threshold, the method comprises disabling the second current Iclamp (e.g., via ClampCtrl_LS). A similar method applies for the high-side GaN FET MN_{HS} discussed with reference to FIG. 4.

At block 801, the low-side GaN FET MN_{LS} is turned on by a controller. As the low-side GaN FET MN_{LS} turns on, the VGS of the low-side GaN FET MN_{LS} rises. At block 802, when the low-side GaN FET MN_{LS} is turned on, the first current Ig,on with a pre-set current amount is injected to the gate of the low-side GaN FET MN_{LS}. For example, the controller sets control TurnOn_MP3a to negative supply voltage (−5V) to turn on transistor MP3a. At block 803, the gate voltage gateV_LS is sensed by comparator 301a. Once the voltage on gateV_LS exceeds Vref (where both gateV_LS and Vref are referenced to the source of the GaN FET MN_{LS}), the output ClampCtrl_LS of comparator 301a goes low to turn on clamp MP_{LSc} as indicated by block 804. Clamp transistor MP_{LSc} discharges gateV_LS as indicated by flow of the second current Iclamp. When the clamp transistor MP_{LSc} is on, the first current Ig,on from the current source also sinks to ground. The current drained by the clamp transistor MP_{LSc} can also be used in an additional voltage loop to adjust or reduce the first current Ig,on to a non-zero value in steady state to save power.

In at least one example, ClampCtrl_LS is used to turn on transistor MP4a when the clamp transistor MP_{LSc} is on. This allows current Iprime to reduce because current Ifb flows through transistor MP4a. As current Iprime reduces, the first current Ig,on reduces, which saves power and prevents overshoot of VGS of the low-side GaN FET MN_{LS} when the clamp transistor MP_{LSc} is on. In at least one example, current Ifb ramps up with some delay and current Iprime and subsequently the first current Ig,on reduce.

After a steady state is achieved and the voltage on gateV_LS sets back to 6V, the second current Iclamp is no longer needed, and the first current Ig,on is reduced to a non-zero value where it provides the exact gate current (e.g., 0.5 mA) to maintain VGS=Vref as indicated by block 805. In at least one example, the first current Ig,on is reduced to a non-zero value to save power. In at least one example, the first current Ig,on is reduced to a zero value. As discussed herein, independent of VGS, the gate current to the gate of low-side GaN FET MN_{LS} is limited to Ig,on=Iref*x, where x=40 . . . 320, in accordance with at least one example. In at least one example, for quick turn-on of the low-side GaN FET MN_{LS}, a pre-charge with higher current can be added. The pre-charge current can be turned off based on fixed or adaptive timing, for instance. In at least one example, for shorter turn-on time (e.g., faster ramp-up of VGS), a second current source with higher current for turn-on can be added, which is shut-off before VGS reaches Vref.

The following are additional examples provided in view of the above-described implementations. Here, one or more features of example, in isolation or in combination, can be combined with one or more features of one or more other examples to form further examples also falling within the scope of the disclosure. As such, one implementation can be combined with one or more other implementation without changing the scope of disclosure.

Example 1 is an apparatus comprising a current source having a current control input and a current source output, the current source output coupled to a first transistor control terminal; a transistor coupled between the first transistor control terminal and a current drain (or sink) terminal, the transistor having a second transistor control terminal; and an amplifier having a first input, a second input, and an amplifier output, the first input coupled to the first transistor control terminal, the second input coupled to a reference terminal, and the amplifier output coupled to the current control input and the second transistor control terminal.

Example 2 is an apparatus according to any example herein, in particular example 1, wherein: the current source is configured to provide a current to the first transistor control terminal responsive to a control signal at the amplifier output; and the transistor is configured, responsive to the control signal, to drain away at least some of the current from the first transistor control terminal.

Example 3 is an apparatus according to any example herein, in particular example 2, wherein the amplifier is configured to set a state of the control signal based on whether a voltage on the first transistor control terminal exceeds a threshold voltage at the reference terminal.

Example 4 is an apparatus according to any example herein, in particular example 3, wherein the amplifier is configured to be: responsive to the voltage being below the threshold voltage, which causes the current source to set the current to a first value; and responsive to the voltage being at or above the threshold voltage, which causes the current source to set the current to a second value, the second value being non-zero and smaller than the first value.

Example 5 is an apparatus according to any example herein, in particular example 4, wherein the amplifier is configured to be: responsive to the voltage being below the threshold voltage, which disables the transistor; and responsive to the voltage being at or above the threshold voltage, which enables the transistor.

Example 6 is an apparatus according to any example herein, in particular example 5, wherein the transistor is enabled before the current source sets the current to the second value, and is disabled after the current source sets the current to the second value.

Example 7 is an apparatus according to any example herein, in particular example 1, further comprising a trimmable current reference coupled to the current source.

Example 8 is an apparatus according to any example herein, in particular example 7, wherein the first transistor control terminal is of a first transistor which is a high electron mobility transistor (HEMT).

Example 9 is an apparatus according to any example herein, in particular example 8, wherein the first transistor control terminal of the HEMT includes a p-type gallium nitride (GaN) layer.

Example 10 is an apparatus according to any example herein, in particular example 8, wherein the first transistor is coupled between a switch terminal and a ground terminal, the current source is coupled to a power supply terminal, and the current drain (or sink) terminal is coupled to the ground terminal.

Example 11 is an apparatus according to any example herein, in particular example 8, wherein the first transistor is coupled between a power terminal and a switching terminal, the current source is coupled to a bootstrap supply terminal, and the current drain (or sink) terminal is coupled to the switching terminal.

Example 12 is an apparatus according to any example herein, in particular example 11, wherein the switching terminal is coupled to a load.

Example 13 is an apparatus comprising: a current source having a current source control input and a current source output, the current source output coupled to a transistor control terminal; a current sink having a current sink control input and coupled between the transistor control terminal and a current drain terminal; and an amplifier having a first input, a second input, and an amplifier output, the first input coupled to the current source output, the second input coupled to a reference terminal, and the amplifier output coupled to the current source control input and the current sink control input.

Example 14 is an apparatus according to any example herein, in particular example 13, wherein the current sink includes a transistor coupled between the current source output and the current drain terminal, the transistor having a second transistor control input coupled to the current sink control input.

Example 15 is an apparatus according to any example herein, in particular example 13, further comprising a trimmable current reference coupled to the current source.

Example 16 is an apparatus according to any example herein, in particular example 13, wherein the transistor control terminal is of a first transistor which is a high electron mobility transistor (HEMT).

Example 17 is an apparatus according to any example herein, in particular example 16, wherein the transistor control terminal of the HEMT includes a p-type gallium nitride (GaN) layer.

Example 18 is an apparatus comprising: a current source and a current sink coupled to a transistor control terminal; and an amplifier configured to control the current source and the current sink by sensing a voltage at the transistor control terminal.

Example 19 is an apparatus according to any example herein, in particular example 18, further comprising a trimmable current reference coupled to the current source.

Example 20 is an apparatus according to any example herein, in particular example 18, wherein the current sink includes a transistor coupled between the transistor control terminal and a current drain terminal.

Example 21 is an apparatus according to any example herein, in particular example 18, wherein the transistor control terminal is of a first transistor which is a high electron mobility transistor (HEMT).

Example 22 is an apparatus according to any example herein, in particular example 21, wherein the transistor control terminal of the HEMT includes a p-type gallium nitride (GaN) layer.

Example 23 is a method comprising: injecting a first current to a control terminal of a transistor; responsive to a voltage of the control terminal exceeding a threshold, reducing the first current, and sinking a second current from the control terminal; and responsive to the voltage being at the threshold, maintaining the first current at a non-zero value.

Example 24 is a method according to any of example herein, in particular example 23, further comprising: responsive to the voltage being below the threshold, disabling the second current.

Example 1a is an apparatus comprising: a current source having a current control input and a current source output; a transistor coupled between the current source output and a current drain terminal, the transistor having a transistor control input; an amplifier having a first input, a second input, and an amplifier output, the first input coupled to the current source output, the second input coupled to a reference terminal, and the amplifier output coupled to the current control input and the transistor control input; and a power transistor having a gate terminal coupled to the first input and the current source output.

Example 2a is an apparatus according to any example herein, in particular example 1a, wherein the current source is configured to provide a current at the current source output, and the amplifier is configured to, responsive to a voltage at the current source output above a threshold voltage at the reference terminal, enable the transistor to drain away at least some of the current from the gate terminal to adjust a voltage on the gate terminal to be at the threshold voltage.

Example 3a is an apparatus according to any example herein, in particular example 2a, wherein the amplifier is configured to: responsive to the voltage being below the threshold voltage, cause the current source to provide a first current at the current source output; and responsive to the voltage being at or above the threshold voltage, cause the current source to provide a second current at the current source output, the second current being smaller than the first current.

Example 4a is an apparatus according to any example herein, in particular example 2a, wherein the threshold voltage is 6V.

Example 5a is an apparatus according to any example herein, in particular example 1a, wherein the power transistor comprises Ga and N.

Example 6a is an apparatus according to any example herein, in particular example 1a, wherein the current drain terminal is a reference supply terminal, and wherein the power transistor is coupled between a switching terminal and the reference supply terminal.

Example 7a is an apparatus according to any example herein, in particular example 1a, wherein the current drain terminal is a supply terminal, and wherein the power transistor is coupled between a switching terminal and the supply terminal.

Example 8a is an apparatus according to any example herein, in particular example 7a, wherein the switching terminal is coupled to a load.

Example 9a is an apparatus comprising: a switching terminal; a first power transistor having a first gate terminal and coupled between the switching terminal and a supply terminal; a second power transistor having a second gate terminal and coupled between the switching terminal and a reference supply terminal; a first current source having a first current control input and a first current source output coupled to the first gate terminal; a second current source having a second current control input and a second current source output coupled to the second gate terminal; a first transistor coupled between the first gate terminal and the switching terminal, the first transistor having a first transistor control input; a second transistor coupled between the second gate terminal and the reference supply terminal, second first transistor having a second transistor control input; a first amplifier having a first input, a second input, and a first amplifier output, the first input coupled to the first gate terminal, the second input coupled to a reference terminal, and the first amplifier output coupled to the first current control input and the first transistor control input; and a second amplifier having a third input, a fourth input, and a second amplifier output, the third input coupled to the second gate terminal, the fourth input coupled to the reference terminal, and the second amplifier output coupled to the second transistor control input and the second transistor control input.

Example 10a is an apparatus according to any example herein, in particular example 9a, wherein the first current source is configured to provide a first current at the first current source output, and the first amplifier is configured to, responsive to a first voltage at the first current source output above a threshold voltage at the reference terminal, enable the first transistor to drain away at least some of the first current from the first gate terminal to adjust a first voltage on the first gate terminal to be at the threshold voltage.

Example 11a is an apparatus according to any example herein, in particular example 10a, wherein the first amplifier is configured to: responsive to the first voltage being below the threshold voltage, cause the first current source to provide a second current at the first current source output; and responsive to the first voltage being at or above the threshold voltage, cause the first current source to provide a third current at the first current source output, the third current being smaller than the second current.

Example 12a is an apparatus according to any example herein, in particular example 9a, wherein the second current source is configured to provide a second current at the first current source output, and the second amplifier is configured to, responsive to a second voltage at the second current source output above a threshold voltage at the reference terminal, enable the second transistor to drain away at least some of the second current from the second gate terminal to adjust a second voltage on the second gate terminal to be at the threshold voltage.

Example 13a is an apparatus according to any example herein, in particular example 12a, wherein the second amplifier is configured to: responsive to the second voltage being below the threshold voltage, cause the second current source to provide a third current at the second current source output; and responsive to the second voltage being at or above the threshold voltage, cause the second current source to provide a fourth current at the second current source output, the fourth current being smaller than the third current.

Example 14a is an apparatus according to any example herein, in particular example 10a, wherein the threshold voltage is 6V.

Example 15a is an apparatus according to any example herein, in particular example 9a, wherein the first power transistor and the second power transistor comprise Ga and N.

Example 16a is an apparatus according to any example herein, in particular example 9a, wherein the switching terminal is coupled to a load.

Example 17a is an apparatus comprising: a power transistor having a gate terminal; and a current limiter circuit configured to limit a current to the gate terminal based on a threshold voltage.

Example 18a is an apparatus according to any example herein, in particular example 17a, wherein the current limiter circuit comprises: a current source having a current control input and a current source output; a transistor coupled between the current source output and a current drain terminal, the transistor having a transistor control input; and an amplifier having a first input, a second input, and an amplifier output, the first input coupled to the current source output, the second input coupled to a reference terminal, and the amplifier output coupled to the current control input and the transistor control input.

Example 19a is an apparatus according to any example herein, in particular example 18a, wherein the gate terminal is coupled to the first input and the current source output.

Example 20a is an apparatus according to any example herein, in particular example 18a, wherein the current source is configured to provide a current at the current source output, and the amplifier is configured to, responsive to a voltage at the current source output above a threshold voltage at the reference terminal, enable the transistor to drain away at least some of the current from the gate terminal to adjust a voltage on the gate terminal to be at the threshold voltage.

Example 21a is an apparatus according to any example herein, in particular example 20a, wherein the amplifier is configured to: responsive to the voltage being below the threshold voltage, cause the current source to provide a first current at the current source output; and responsive to the voltage being at or above the threshold voltage, cause the current source to provide a second current at the current source output, the second current being smaller than the first current.

Example 22a is an apparatus according to any example herein, in particular example 20a, wherein the current drain terminal is a reference supply terminal, and wherein the power transistor is coupled between a switching terminal and the reference supply terminal.

Example 23a is an apparatus according to any example herein, in particular example 20a, wherein the current drain terminal is a supply terminal, and wherein the power transistor is coupled between a switching terminal and the supply terminal.

Example 24a is an apparatus according to any example herein, in particular example 17a, wherein the power transistor comprises Ga and N.

Besides what is described herein, various modifications can be made to disclose implementations and implementations thereof without departing from their scope. Therefore, illustrations of implementations herein should be construed as examples, and not restrictive to scope of present disclosure.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuit or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuit. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors, or other types of device structure transistors. Furthermore, the devices may be implemented in/over a silicon substrate (Si), a silicon carbide substrate (SiC), a gallium nitride substrate (GaN), or a gallium arsenide substrate (GaAs).

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately,” or “substantially” preceding a parameter means being within +/−10 percent of that parameter or, if the parameter is zero, a reasonable range of values around zero.

What is claimed is:

1. An apparatus comprising:
a current source having a current control input and a current source output, the current source output coupled to a first transistor control terminal;
a transistor coupled between the first transistor control terminal and a current drain terminal, the transistor having a second transistor control terminal; and
an amplifier having a first input, a second input, and an amplifier output, the first input coupled to the first transistor control terminal, the second input coupled to a reference terminal, and the amplifier output coupled to the current control input and the second transistor control terminal.

2. The apparatus of claim 1, wherein:
the current source is configured to provide a current to the first transistor control terminal responsive to a control signal at the amplifier output; and
the transistor is configured, responsive to the control signal, to drain away at least some of the current from the first transistor control terminal.

3. The apparatus of claim 2, wherein the amplifier is configured to set a state of the control signal based on whether a voltage on the first transistor control terminal exceeds a threshold voltage at the reference terminal.

4. The apparatus of claim 3, wherein the amplifier is configured to:
responsive to the voltage being below the threshold voltage, cause the current source to set the current to a first value; and
responsive to the voltage being at or above the threshold voltage, cause the current source to set the current to a second value, the second value being non-zero and smaller than the first value.

5. The apparatus of claim 4, wherein the amplifier is configured to:
responsive to the voltage being below the threshold voltage, which disables the transistor; and
responsive to the voltage being at or above the threshold voltage, which enables the transistor.

6. The apparatus of claim 5, wherein the transistor is enabled before the current source sets the current to the second value, and is disabled after the current source sets the current to the second value.

7. The apparatus of claim 1, further comprising a trimmable current reference coupled to the current source.

8. The apparatus of claim 7, wherein the first transistor control terminal is of a first transistor which is a high electron mobility transistor (HEMT).

9. The apparatus of claim 8, wherein the first transistor control terminal of the HEMT includes a p-type gallium nitride (GaN) layer.

10. The apparatus of claim 8, wherein the first transistor is coupled between a switch terminal and a ground terminal, the current source is coupled to a power supply terminal, and the current drain terminal is coupled to the ground terminal.

11. The apparatus of claim 8, wherein the first transistor is coupled between a power terminal and a switching terminal, the current source is coupled to a bootstrap supply terminal, and the current drain terminal is coupled to the switching terminal.

12. The apparatus of claim 11, wherein the switching terminal is coupled to a load.

13. An apparatus comprising:
a current source having a current source control input and a current source output, the current source output coupled to a transistor control terminal;
a current sink having a current sink control input and coupled between the transistor control terminal and a current drain terminal; and
an amplifier having a first input, a second input, and an amplifier output, the first input coupled to the current source output, the second input coupled to a reference terminal, and the amplifier output coupled to the current source control input and the current sink control input.

14. The apparatus of claim 13, wherein the current sink includes a transistor coupled between the current source output and the current drain terminal, the transistor having a second transistor control input coupled to the current sink control input.

15. The apparatus of claim 13, further comprising a trimmable current reference coupled to the current source.

16. The apparatus of claim 13, wherein the transistor control terminal is of a first transistor which is a high electron mobility transistor (HEMT).

17. The apparatus of claim 16, wherein the transistor control terminal of the HEMT includes a p-type gallium nitride (GaN) layer.

18. An apparatus comprising:
a current source and a current sink coupled to a transistor control terminal; and
an amplifier configured to control the current source and the current sink by sensing a voltage at the transistor control terminal.

19. The apparatus of claim 18, further comprising a trimmable current reference coupled to the current source.

20. The apparatus of claim 18, wherein the current sink includes a transistor coupled between the transistor control terminal and a current drain terminal.

21. The apparatus of claim 18, wherein the transistor control terminal is of a first transistor which is a high electron mobility transistor (HEMT).

22. The apparatus of claim 21, wherein the transistor control terminal of the HEMT includes a p-type gallium nitride (GaN) layer.

23. A method comprising:
injecting a first current to a control terminal of a transistor;
responsive to a voltage of the control terminal exceeding a threshold, reducing the first current, and sinking a second current from the control terminal; and
responsive to the voltage being at the threshold, maintaining the first current at a non-zero value.

24. The method of claim 23, further comprising: responsive to the voltage being below the threshold, disabling the second current.
